(19) United States
(12) Patent Application Publication
(10) Pub. No.: US 2025/0070085 A1
(43) Pub. Date: Feb. 27, 2025

(54) SEMICONDUCTOR DEVICE AND METHODS OF FORMING THE SAME

(71) Applicant: Taiwan Semiconductor Manufacturing Co., Ltd., Hsinchu (TW)

(72) Inventors: Tsang-Jiuh Wu, Hsinchu (TW); Shih-Che Lin, Toufen Township (TW); Cheng-Chun Tsai, Hsinchu (TW); Ping-Jung Wu, Hsinchu (TW); Hao-Wen Ko, Hsinchu (TW)

(21) Appl. No.: 18/401,949

(22) Filed: Jan. 2, 2024

Related U.S. Application Data
(60) Provisional application No. 63/608,921, filed on Dec. 12, 2023.
(60) Provisional application No. 63/578,435, filed on Aug. 24, 2023.

(51) Int. Cl. H01L 25/065; H01L 21/56; H01L 23/00

(52) U.S. Cl. CPC H01L 25/0657; H01L 21/56; H01L 24/08; H01L 24/80; H01L 2224/08145; H01L 2224/80895; H01L 2225/06548

(57) ABSTRACT

A method includes: forming first bond pads along a wafer; bonding a first die to a first set of the first bond pads, the first die being electrically connected to the wafer; depositing a gap-fill dielectric over the wafer and around the first die; forming openings in the gap-fill dielectric; forming first active through vias in physical contact with the second set of the first bond pads and first dummy through vias in physical contact with the third set of the first bond pads, the first active through vias being electrically connected to the wafer, the first dummy through vias being electrically isolated from the wafer; forming second bond pads along the first die, the first active through vias, and the first dummy through vias; and bonding a second die to the first die and to a first active via of the first active through vias.

### PRIORITY CLAIM AND CROSS-REFERENCE

This application claims the benefit of U.S. Provisional Application No. 63/608,921, filed on Dec. 12, 2023 and claims the benefit of U.S. Provisional Application No. 63/578,435, filed on Aug. 24, 2023, which applications are hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a desire for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are cross-sectional views of integrated circuit dies, in accordance with various embodiments.

FIGS. 2-15 are cross-sectional views of intermediate stages in the manufacturing of a die structure, in accordance with some embodiments.

FIG. 16 is a cross-sectional view of an intermediate stage in the manufacturing of an integrated circuit package, in accordance with some embodiments.

FIGS. 17A-17K are plan views of intermediate stages in the manufacturing of a die structure, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The disclosure provides embodiments for forming a die structure comprising one or more integrated circuit dies, active through vias, and dummy through vias. The die structure may be incorporated into an integrated circuit package, such as a system-on-integrated-chips (SoIC) device, although other types of devices or packages may be formed. The dummy through vias provide various benefits, such as thermal dissipation among the electrically connected elements, and may be formed simultaneously with the active through vias. The resulting semiconductor device may be fabricated with greater yield and improved performance.

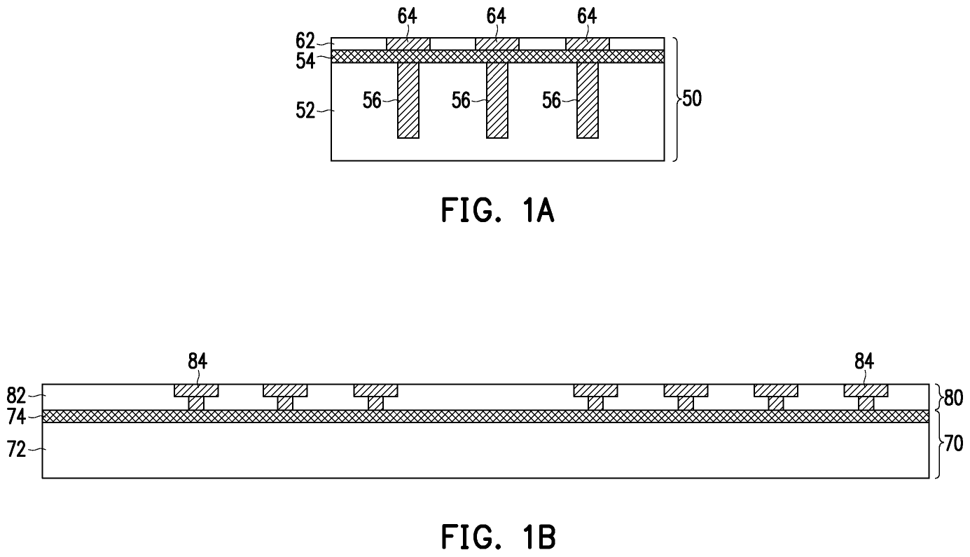

FIGS. 1A and 1B illustrate components which will be combined to form a die structure which may be part of an integrated circuit package, in accordance with various embodiments. FIG. 1A illustrates an integrated circuit die which may be singulated from a wafer and be utilized as a top die of the die structure. FIG. 1B illustrates an integrated circuit die which may remain in wafer form and utilized as a bottom die of the die structure.

FIG. 1A is a cross-sectional view of an integrated circuit die 50. The integrated circuit die 50 will be bonded to other dies in subsequent processing to form a die structure. The integrated circuit die 50 may be a logic die (e.g., central processing unit (CPU), graphics processing unit (GPU), system-on-a-chip (SoC), application processor (AP), microcontroller, etc.), a memory die (e.g., dynamic random access memory (DRAM), static random access memory (SRAM), etc.), a bridge die (e.g., a local silicon interconnect (LSI)), a power management die (e.g., power management integrated circuit (PMIC)), a radio frequency (RF) die, an interface die, a sensor die, a micro-electro-mechanical-system (MEMS) die, a signal processing die (e.g., digital signal processing (DSP)), a front-end die (e.g., analog front-end (AFE)), the like, or combinations thereof.

The integrated circuit die 50 may be formed in a wafer, which may include different device regions that are singulated to form a plurality of integrated circuit dies. The integrated circuit die 50 may be processed according to applicable manufacturing processes to form integrated circuits. For example, the integrated circuit die 50 includes a semiconductor substrate 52, which may be a substrate of silicon, doped or undoped, or an active layer of a semiconductor-on-insulator (SOI) substrate. The semiconductor substrate 52 may include other semiconductor materials, such as germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. Other substrates, such as multi-layered or gradient substrates, may also be used. The semiconductor substrate 52 has an active surface (e.g., the surface facing upward in FIG. 1) and an inactive surface (e.g., the surface facing downward in FIG. 1). Devices (not separately illustrated) may be formed in and/or on the active surface of the semiconductor substrate 52. The devices may be active devices (e.g., transistors, diodes, etc.) and/or passive devices (e.g., capacitors, inductors, resistors, etc.). The inactive surface may be free from devices.

An interconnect structure 54 is disposed over the active surface of the semiconductor substrate 52, and is used to electrically connect the devices of the semiconductor substrate 52 to form an integrated circuit. The interconnect structure 54 may include one or more dielectric layer(s) and respective metallization layer(s) in the dielectric layer(s). The dielectric layer(s) may be, e.g., low-k dielectric layer(s). The metallization layer(s) may include conductive vias and/or conductive lines to interconnect the devices of the semiconductor substrate 52. The metallization layer(s) may be formed of a conductive material, such as a metal, such as copper, cobalt, aluminum, gold, combinations thereof, or the like. The metallization layer(s) of the interconnect structure 54 may be formed by a damascene process, such as a single damascene process, a dual damascene process, or the like.

Optionally, conductive vias 56 extend into the interconnect structure 54 and/or the semiconductor substrate 52. The conductive vias 56 are electrically coupled to the metallization layer(s) of the interconnect structure 54. As an example to form the conductive vias 56, recesses can be formed in the interconnect structure 54 and/or the semiconductor substrate 52 by, for example, etching, milling, laser techniques, a combination thereof, or the like. A thin barrier layer may be conformally deposited in the recesses, such as by chemical vapor deposition (CVD), atomic layer deposition (ALD), physical vapor deposition (PVD), thermal oxidation, a combination thereof, or the like. The barrier layer may be formed of an oxide, a nitride, combinations thereof, or the like. A conductive material may be formed over the barrier layer and in the recesses. The conductive material may be formed by an electro-chemical plating process, CVD, ALD, PVD, a combination thereof, or the like. Examples of conductive materials include copper, tungsten, aluminum, silver, gold, a combination thereof, or the like. Excess conductive material and barrier layer is removed from a surface of the interconnect structure 54 or the semiconductor substrate 52 by, for example, a chemical-mechanical polish (CMP). The remaining portions of the barrier layer and conductive material in the recesses form the conductive vias 56. After their initial formation, the conductive vias 56 may be buried in the semiconductor substrate 52. The semiconductor substrate 52 may be thinned in subsequent processing to expose the conductive vias 56 at the inactive surface of the semiconductor substrate 52. After the exposure process, the conductive vias 56 are through-substrate vias (TSVs), such as through-silicon vias, that extend through the semiconductor substrate 52.

A dielectric layer 62 is over the interconnect structure 54, at the front-side of the integrated circuit die 50. The dielectric layer 62 may be formed of an oxide such as silicon oxide, phosphosilicate glass (PSG), borosilicate glass (BSG), boron-doped phosphosilicate glass (BPSG), a tetraethyl orthosilicate (TEOS) based oxide, or the like; a nitride such as silicon nitride or the like; a polymer such as polybenzoxazole (PBO), polyimide, a benzocyclobutene (BCB) based polymer, or the like; a combination thereof; or the like. The dielectric layer 62 may be formed, for example, by CVD, spin coating, lamination, or the like. Optionally, one or more passivation layer(s) (not separately illustrated) are disposed between the dielectric layer 62 and the interconnect structure 54.

Die connectors 64 extend through the dielectric layer 62. The die connectors 64 may include conductive pillars, pads, or the like, to which external connections can be made. In some embodiments, the die connectors 64 include bond pads (e.g., metal pads) at the front-side of the integrated circuit die 50, and include bond pad vias that connect the bond pads to an upper metallization layer of the interconnect structure 54. In such embodiments, the die connectors 64 (including the bond pads and the bond pad vias) may be formed by a damascene process, such as a single damascene process, a dual damascene process, or the like. The die connectors 64 may be formed of a suitable conductive material, such as copper, tungsten, aluminum, silver, gold, a combination thereof, or the like, which can be formed by, for example, plating or the like.

Optionally, chip probe (CP) testing may be performed on the integrated circuit die 50. For example, a chip probe may be attached to test pads (not separately illustrated). Chip probe testing may be performed on the integrated circuit die 50 to ascertain whether the integrated circuit die 50 is a known good die (KGD). Thus, only integrated circuit dies 50, which are KGDs, undergo subsequent processing are packaged, and dies which fail the chip probe testing are not packaged.

FIG. 1B is a cross-sectional view of an integrated circuit die 70 (e.g., an integrated circuit wafer 70). The integrated circuit die 50 will be bonded to the integrated circuit die 70 in subsequent processing to form a die structure. The integrated circuit die 70 may be a logic die (e.g., CPU, GPU, SoC, AP, microcontroller, etc.), a memory die (e.g., DRAM, SRAM, etc.), a bridge die (e.g., LSI), a power management die (e.g., PMIC), an RF die, an interface die, a sensor die, a MEMS die, a signal processing die (e.g., DSP), a front-end die (e.g., AFE), the like, or combinations thereof.

The integrated circuit die 70 may be formed in a wafer which may include different device regions 70D. However, in accordance with some embodiments, the different device regions 70D may remain unsingulated to form a plurality of integrated circuit dies 70 within the wafer form. The integrated circuit die 70 may be processed according to applicable manufacturing processes to form integrated circuits. The integrated circuit die 70 may include a substrate 72 formed of similar materials as described above in connection with the semiconductor substrate 52 and an interconnect structure 74 formed similarly as described above in connection with the interconnect structure 54. Note that the integrated circuit die 70 may not include conductive vias like the conductive vias 56 of the integrated circuit die 50. However, in other embodiments, the integrated circuit die 70 may include analogous conductive vias which may be utilized for back side routing and/or external electrical connection.

In some embodiments, a bonding structure 80 is formed along the front side of the integrated circuit die 70. The bonding structure 80 is formed over the interconnect structure 74 of the integrated circuit die 70 and will be utilized in a subsequent bonding process. The bonding structure 80 includes a bonding layer 82 formed of a dielectric material, which can be an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like. The bonding structure 80 further includes bond pads 84 (e.g., metal pads) formed in the bonding layer 82. The bond pads 84 are electrically connected to the interconnect structure 74. For example, the bond pads 84 may be formed by a damascene process, such as a single damascene process, a dual damascene process, or the like. The bond pads 84 can be formed of a conductive material, such as a metal, such as copper, aluminum, or the like, which can be formed by, for example, plating, or the like. In some embodiments, a planarization process such as a chemical mechanical polish (CMP), an etch-back process, combinations thereof, or the like is performed on the bond pads 84 and the bonding layer 82. After the planarization process, surfaces of the bond pads 84 and the bonding layer 82 are substantially coplanar (within process variations). As illustrated, the bond pads 84 may include pad portions and via portions connecting the pad portions to the interconnect structure 74.

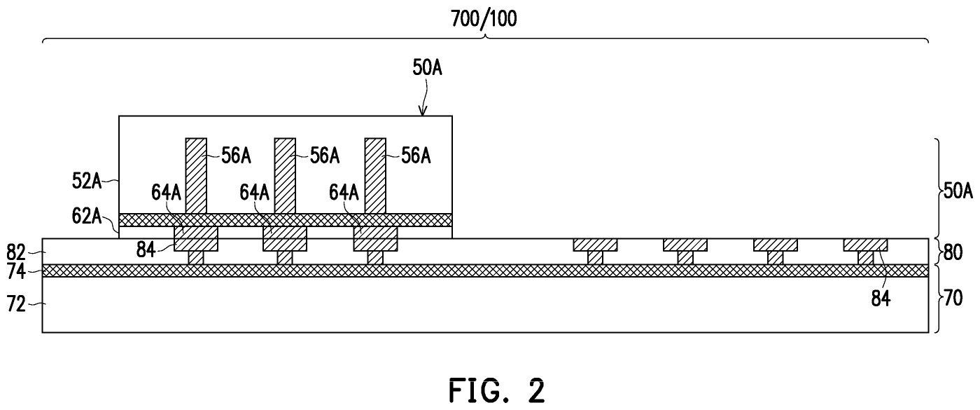

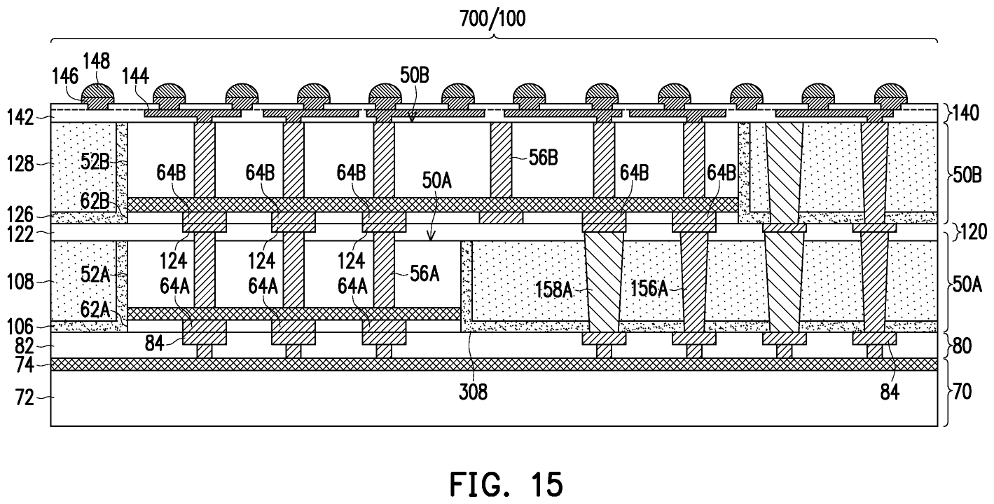

FIGS. 2-16 are cross-sectional views of intermediate stages in the manufacturing of a die structure 100 (see FIG. 15), in accordance with some embodiments. The die structure 100 is a stack of integrated circuit dies (including integrated circuit die 70, first integrated circuit dies 50A, and second integrated circuit dies 50B). The die structure 100 is formed by bonding the integrated circuit dies 50 together on a device region 70D of the integrated circuit die 70. The device region 70D will be singulated to form the die structure 100. Processing of one device region 70D of the integrated circuit die 70 is illustrated, but it should be appreciated that any number of device regions 70D (e.g., along the integrated circuit die 70 being in wafer form) can be simultaneously processed to form any number of the die structures 100.

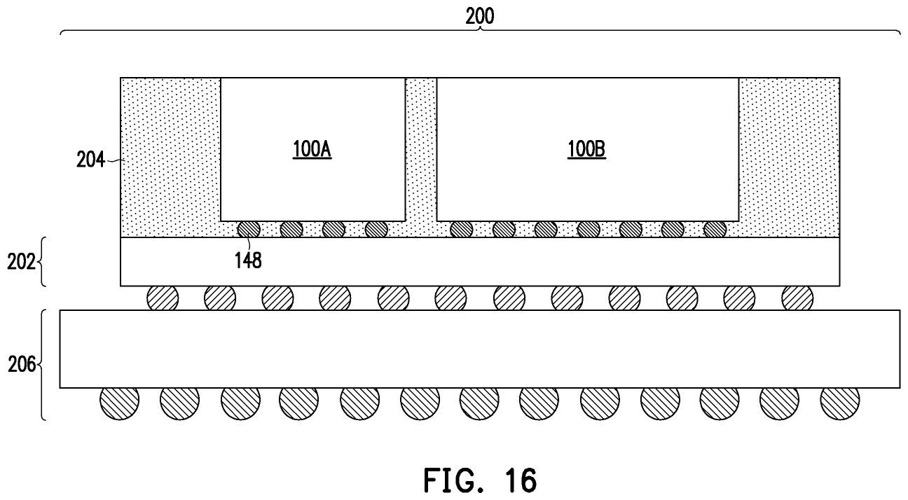

A die structure 100 is a component that may be subsequently packaged to form an integrated circuit package (see FIG. 16). The integrated circuit dies of the die structure 100 may be heterogeneous dies. Packaging the die structure 100 in lieu of packaging the dies individually may allow heterogeneous dies to be integrated with a small footprint. The die structure 100 may be a system-on-integrated-chips (SoIC) device, although other types of devices may be formed.

In FIG. 2, one or more first integrated circuit dies 50A (e.g., a first tier of top dies of the die structure 100) are attached to the integrated circuit die 70 (e.g., a bottom die of the die structure 100) in a face-down manner, such that the front sides of the first integrated circuit dies 50A are attached to the bonding structure 80 (e.g., the bonding layer 82 and the bond pads 84) along the integrated circuit wafer 70. The dielectric layers 62A and the die connectors 64A of the first integrated circuit dies 50A are attached to the bonding structure 80. The first integrated circuit dies 50A may be placed by, e.g., a pick-and-place process. In the illustrated embodiment, two first integrated circuit dies 50A are placed in the device region 70D, although any desired quantity of first integrated circuit dies 50A may be placed in the device region 70D. The first integrated circuit dies 50A may be logic devices, such as CPUs, GPUs, SoCs, microcontroller, or the like.

As discussed above, the integrated circuit die 70 may be a wafer, such that multiple die structures 100 can be formed on the multiple individual integrated circuit dies 70 simultaneously.

The first integrated circuit dies 50A may be attached by bonding the first integrated circuit dies 50A to the bonding structure 80. As described above, the bonding structure 80 is on the front side of the first integrated circuit die 70.

For example, the dielectric layers 62A of the first integrated circuit dies 50A are directly bonded to the bonding layer 82 through dielectric-to-dielectric bonding, without using any adhesive material (e.g., die attach film). The die connectors 64A of the first integrated circuit dies 50A are directly bonded to the bond pads 84 through metal-to-metal bonding, without using any eutectic material (e.g., solder). The bonding may include a pre-bonding and an annealing. During the pre-bonding, a small pressing force is applied to press the first integrated circuit dies 50A against the bonding layer 82. The pre-bonding is performed at a low temperature, such as about room temperature, and after the pre-bonding, the dielectric layers 62A are bonded to the bonding layer 82. The bonding strength is then improved in a subsequent annealing step, in which the bonding layer 82, the bond pads 84, the dielectric layers 62A, and the die connectors 64A are annealed. After the annealing, direct bonds such as fusion bonds are formed, bonding the bonding layer 82 to the dielectric layers 62A. For example, the bonds can be covalent bonds between the material of the bonding layer 82 and the material of the dielectric layers 62A. The bond pads 84 may be connected to the die connectors 64A with a one-to-one correspondence. The bond pads 84 and the die connectors 64A may be in physical contact after the pre-bonding, or may expand to be brought into physical contact during the annealing. Further, during the annealing, the material of the bond pads 84 and the die connectors 64A (e.g., copper) intermingles, so that metal-to-metal bonds are also formed. Hence, the resulting bonds between the first integrated circuit dies 50A, the bonding layer 82, and the bond pads 84 include both dielectric-to-dielectric bonds and metal-to-metal bonds.

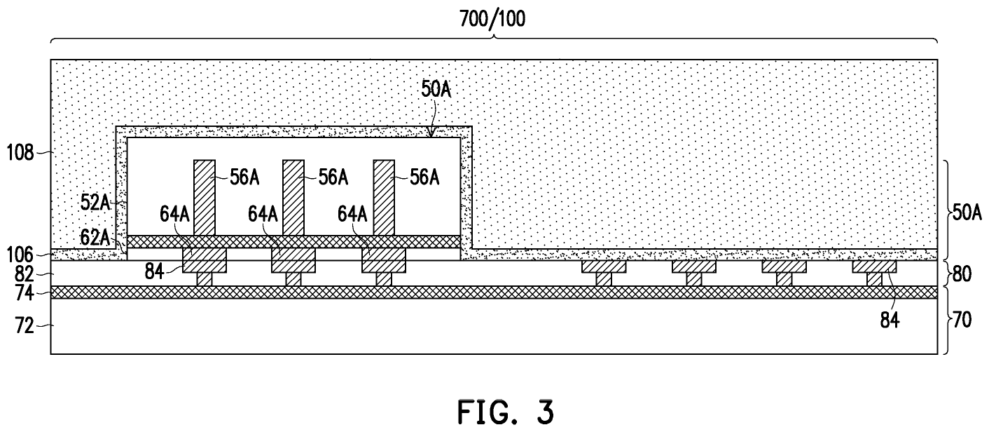

In FIG. 3, a buffer layer 106 is deposited over the integrated circuit dies 70 and around the first integrated circuit dies 50A. The buffer layer 106 is a liner layer that an overlying gap-fill dielectric will be formed on. The buffer layer 106 may protect the first integrated circuit dies 50A and the integrated circuit dies 70 from damage during subsequent processes such as forming the gap-fill dielectric.

The buffer layer 106 may be formed of dielectric materials, such as silicon nitride, silicon oxynitride, silicon carbide, silicon carbonitride, silicon oxycarbide, aluminum nitride, gallium nitride, zinc oxide, combinations thereof, and the like. The buffer material may be formed by a sputtering process such as a physical vapor deposition (PVD); a chemical deposition process such as chemical vapor deposition (CVD), atomic layer deposition (ALD), or the like; a spray coating process; or the like.

A gap-fill dielectric 108 is then formed on the buffer layer 106. The gap-fill dielectric 108 and the buffer layer 106 are around and between the first integrated circuit dies 50A in the device region 70D over the integrated circuit dies 70. Initially, the gap-fill dielectric 108 and the buffer layer 106 may bury or cover the first integrated circuit dies 50A, such that the top surfaces of the gap-fill dielectric 108 and the buffer layer 106 are above the top surfaces of the first integrated circuit dies 50A.

The gap-fill dielectric 108 may be formed of dielectric materials such as silicon nitride, silicon oxynitride, silicon carbide, silicon carbonitride, silicon oxycarbide, aluminum nitride, gallium nitride, zinc oxide, boron nitride, beryllium oxide, combinations thereof, and the like. The gap-fill dielectric 108 may be formed by a sputtering process such as a physical vapor deposition (PVD); a chemical deposition process such as chemical vapor deposition (CVD), atomic layer deposition (ALD), or the like; a spray coating process; or the like. The gap-fill dielectric 108 may be formed by depositing the gap-fill dielectric 108 with a spray coating process or with a chemical deposition process, such as chemical vapor deposition (CVD), atomic layer deposition (ALD), or the like. In some embodiments, materials of the buffer layer 106 and the gap-fill dielectric 108 may be selected to have different etch selectivities in order for the buffer layer 106 to serve as an etch stop layer during subsequent etching steps.

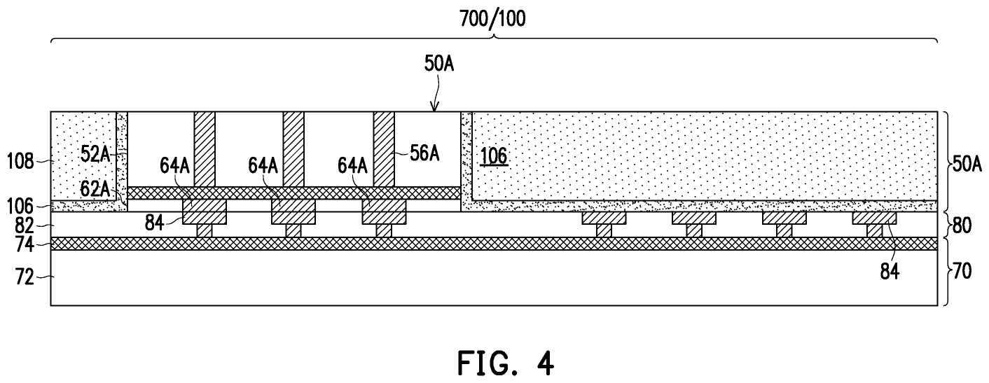

In FIG. 4, a removal process is performed to level the top surfaces of the gap-fill dielectric 108 and the buffer layer 106 with the inactive (e.g., back side) surfaces of the first integrated circuit dies 50A. In some embodiments, a planarization process such as a chemical mechanical polish (CMP), an etch-back process, combinations thereof, or the like is utilized. After the planarization process, surfaces of the gap-fill dielectric 108, the buffer layer 106, and the first integrated circuit dies 50A (including the semiconductor substrates 52A) are substantially coplanar (within process variations). The conductive vias 56A of the first integrated circuit dies 50A may remain buried by the semiconductor substrates 52A after this removal process.

In accordance with some embodiments, the semiconductor substrates 52A are then thinned to expose the conductive vias 56A. Portions of the gap-fill dielectric 108 and the buffer layer 106 may also be removed by the thinning process. The thinning process may be, for example, a grinding process, a CMP, an etch-back process, a combination thereof, or the like, which is performed at the back sides of the first integrated circuit dies 50A.

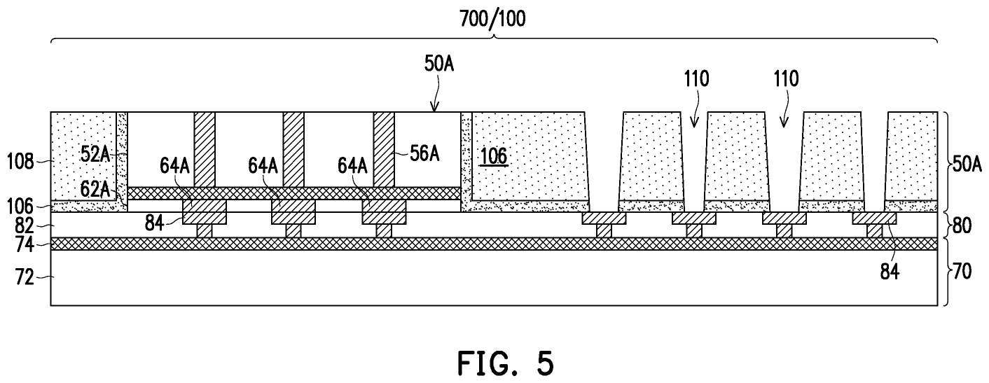

In FIG. 5, an etching process is performed to form openings 110 that expose some of the bond pads 84, such as bond pads 84 which do not have the first integrated circuit dies 50A directly attached. The openings 110 may be formed using any suitable process such as photolithography and etching. For example, the openings 110 can be formed by etching, milling, laser techniques, a combination thereof, or the like. The etching process may include one or more isotropic etching and/or anisotropic etching processes. For example, a first etching process may be used to form the openings 110 to expose the buffer layer 106, and a second etching process may be used to extend the openings 110 to expose the underlying bond pads 84.

As discussed in greater detail below, the openings 110 may have a variety of shapes and dimensions. For example, some of the openings 110A will be used for active through vias while others of the openings 110D will be used for dummy through vias. As such, the openings 110A and the openings 110B may have same, similar, or different shapes as well as same, similar, or different dimensions.

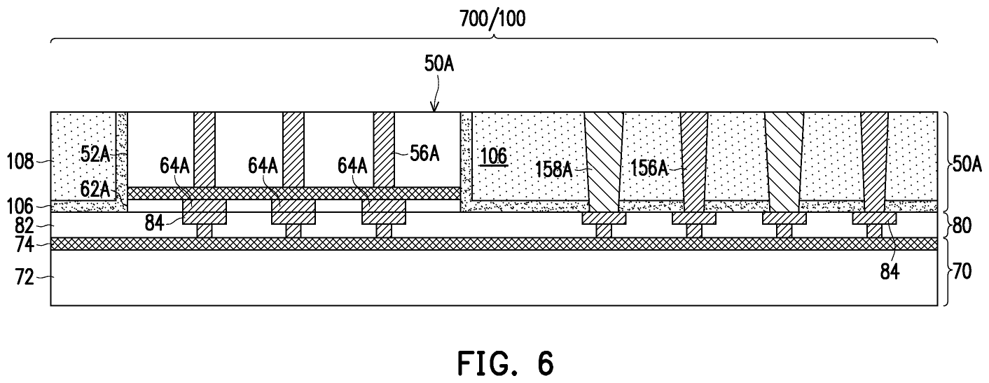

In FIG. 6, the openings 110 are filled with conductive material to form through vias 156A. The through vias 156A/158A include active through vias 156A and dummy through vias 158A. The active through vias 156A will be electrically connected to other integrated circuits of the die structure (e.g., the integrated circuit dies 50/70). The dummy through vias 158A will be electrically isolated from the integrated circuits of the die structure (e.g., the integrated circuit dies 50/70 as well as the active through vias 156A). In some embodiments, the dummy through vias 158A may be connected to conductive elements on or connected to some of the integrated circuit dies 50/70, however, such that the dummy through vias 158A remain electrically isolated from the integrated circuits within those integrated circuit dies 50/70. The active through vias 156A and the dummy through vias 158A may be formed in a variety of layouts that differ from the cross-section as illustrated in FIG. 6 for simplicity. For example, FIGS. 16A through 16K are provided to illustrate and describe various other arrangement styles that may be utilized. Note that by forming the openings 110 and the through vias 156A/158A at this part of the process ensures that the buffer layer 106 and the gap-fill dielectric 108 may be formed crack-free, seam-free, and at a higher deposition rate and yield.

In accordance with some embodiments, a thin barrier layer may be conformally deposited in the openings 110, such as by CVD, ALD, PVD, thermal oxidation, a combination thereof, or the like. The barrier layer may be formed of an oxide, a nitride, combinations thereof, or the like. A conductive material may be formed over the barrier layer and in the openings 110. The conductive material may be formed by an electro-chemical plating process, CVD, ALD, PVD, a combination thereof, or the like. Examples of conductive materials include copper, tungsten, aluminum, silver, gold, the like, or alloys or combinations thereof. Excess conductive material and barrier layer is removed from a surface of the gap-fill dielectric 108 and the buffer layer 106 by, for example, a CMP. The remaining portions of the barrier layer and conductive material in the openings 110 form the through vias 156A/158A.

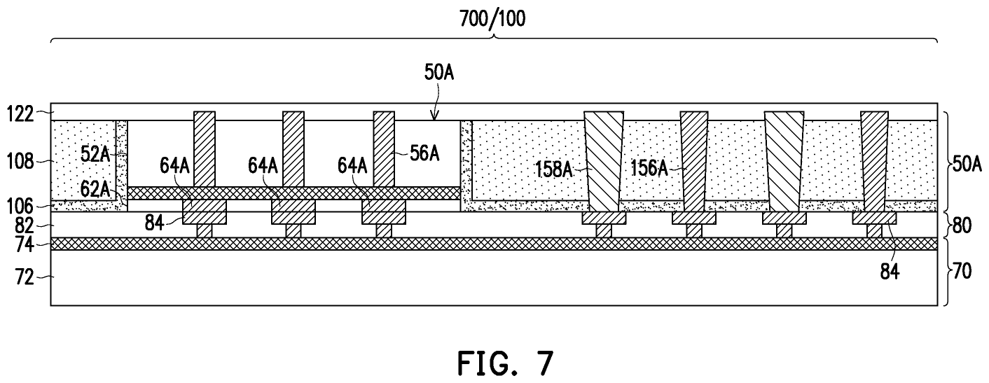

In FIG. 7, the semiconductor substrates 52A are recessed to expose upper portions of the sidewalls of the conductive vias 56A and the through vias 156A/158A. The recessing may be by an etching process, such as a dry etch, a wet etch, or combinations thereof. After the recessing, the conductive vias 56A protrude from the inactive surfaces of the semiconductor substrates 52A and the through vias 156A/158A protrude from upper surfaces of the gap-fill dielectric 108 and the buffer layer 106.

In addition, a bonding layer 122 is then formed on the gap-fill dielectric 108, the buffer layer 106, and the back sides of the first integrated circuit dies 50A. The bonding layer 122 is around portions of the sidewalls of the conductive vias 56A and the through vias 156A/158A. The bonding layer 122 may bury or cover the conductive vias 56A and the through vias 156A/158A, such that the top surface of the bonding layer 122 is above the surfaces of the conductive vias 56A and the through vias 156A/158A. The bonding layer 122 will be utilized in a subsequent bonding process, and may help electrically isolate the conductive vias 56A and the through vias 156A/158A from one another, thus avoiding shorting. The bonding layer 122 is formed of a dielectric material. The dielectric material can be an oxide such as silicon oxide, phosphosilicate glass (PSG), borosilicate glass (BSG), boron-doped phosphosilicate glass (BPSG), a tetraethyl orthosilicate (TEOS) based oxide, or the like, which may be formed by a suitable deposition process such as chemical vapor deposition (CVD), atomic layer deposition (ALD), or the like.

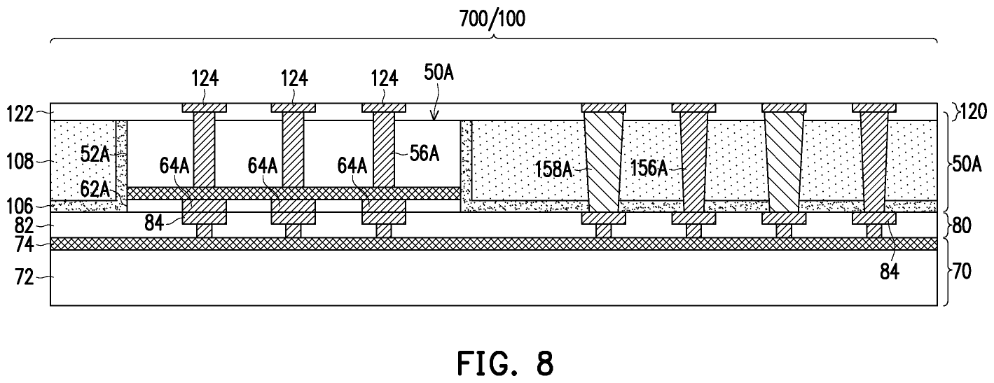

In FIG. 8, bond pads 124 (e.g., metal pads) are formed in the bonding layer 122. The bonding layer 122 and the bond pads 124 may collectively be referred to as a bonding structure 120. The bond pads 124 are connected to the conductive vias 56A and the through vias 156A/158A. For example, the bond pads 124 may be formed with electrical connection to the active through vias 156A and may or may not also be formed with electrical connection to the dummy through vias 158A. The bond pads 124 may be formed by a damascene process, such as a single damascene process, a dual damascene process, or the like. The bond pads 124 can be formed of a conductive material, such as a metal, such as copper, aluminum, or the like, which can be formed by, for example, plating, or the like. In some embodiments, a planarization process such as a CMP, an etch-back process, combinations thereof, or the like is performed on the bond pads 124, and the bonding layer 122. After the planarization process, surfaces of the bond pads 124 and the bonding layer 122 are substantially coplanar (within process variations).

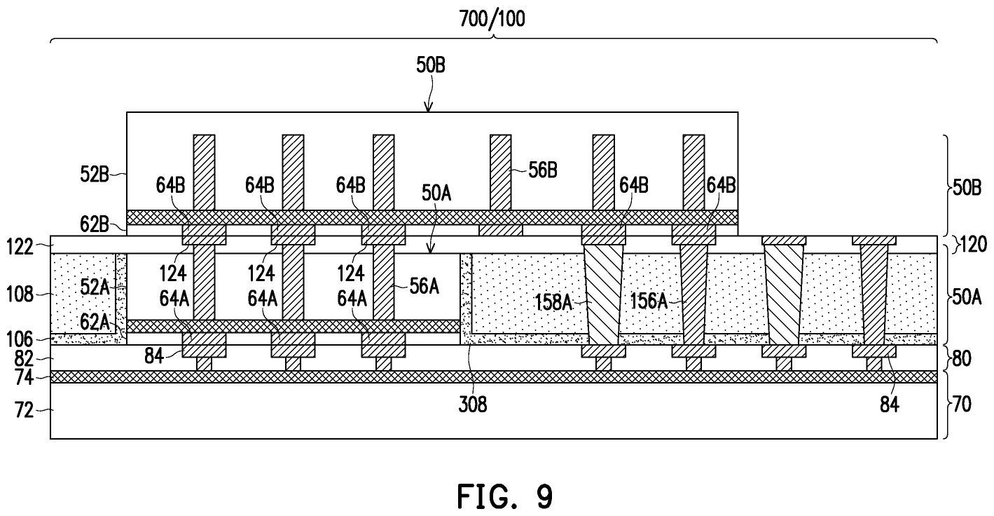

In FIG. 9, second integrated circuit dies 50B (e.g., a second tier of top dies of the die structure 100) are attached to the first integrated circuit dies 50A (e.g., the first tier of top dies of the die structure 100) via the bonding structure 120 (e.g., the bonding layer 112 and the bond pads 124), such that the front sides of the second integrated circuit dies 50B face the back-sides of the first integrated circuit dies 50A. In the illustrated embodiment, one second integrated circuit die 50B is attached above and electrically connected to the first integrated circuit die 50A and some of the through vias 156A/158A, although any desired quantity of second integrated circuit dies 50B may be attached above each first integrated circuit die 50A. The second integrated circuit dies 50B may be memory devices, such as dynamic random access memory (DRAM) dies, static random access memory (SRAM) dies, hybrid memory cube (HMC) modules, high bandwidth memory (HBM) modules, or the like. The second integrated circuit dies 50B may be logic devices, such as CPUs, GPUs, SoCs, microcontroller, or the like.

As illustrated, the second integrated circuit die 50B may have connections with some of the active through vias 156A and/or dummy through vias 158A. In such embodiments, the second integrated circuit die 50B may be electrically connected to the active through vias 156A. Although elements of the second integrated circuit die 50B may similarly have an electrical connection with the dummy through vias 158A, these elements may also be dummy elements within the second integrated circuit die 50B. As such, those dummy through vias 158A remain electrically isolated from the integrated circuit of the second integrated circuit die 50B and thus remain electrically isolated from the electrically connected elements (e.g., the integrated circuit dies 50/70 and the active through vias 156) of the die structure 100.

The second integrated circuit dies 50B may be attached to the bonding structure 120 (e.g., the bonding layer 122 and the bond pads 124) by placing the second integrated circuit dies 50B on the bonding layer 122 and the bond pads 124, then bonding the second integrated circuit dies 50B to the first integrated circuit dies 50A via the bonding layer 122 and the bond pads 124. The second integrated circuit dies 50B may be placed by, e.g., a pick-and-place process. As an example of the bonding process, the second integrated circuit dies 50B may be bonded to the bonding layer 122 and the bond pads 124 by dielectric-to-dielectric and metal-to-metal bonding.

For example, the dielectric layers 62B of the second integrated circuit dies 50B are directly bonded to the bonding layer 122 through dielectric-to-dielectric bonding, without using any adhesive material (e.g., die attach film). The die connectors 64B of the second integrated circuit dies 50B are directly bonded to the bond pads 124 through metal-to-metal bonding, without using any eutectic material (e.g., solder). The bonding may include a pre-bonding and an annealing. During the pre-bonding, a small pressing force is applied to press the second integrated circuit dies 50B against the bonding layer 122. The pre-bonding is performed at a low temperature, such as about room temperature, and after the pre-bonding, the dielectric layers 62B are bonded to the bonding layer 122. The bonding strength is then improved in a subsequent annealing step, in which the bonding layer 122, the bond pads 124, the dielectric layers 62B, and the die connectors 64B are annealed. After the annealing, direct bonds such as fusion bonds are formed, bonding the bonding layer 122 to the dielectric layers 62B. For example, the bonds can be covalent bonds between the material of the bonding layer 122 and the material of the dielectric layers 62B. The bond pads 124 are connected to the die connectors 64B with a one-to-one correspondence. The bond pads 124 and the die connectors 64B may be in physical contact after the pre-bonding, or may expand to be brought into physical contact during the annealing. Further, during the annealing, the material of the bond pads 124 and the die connectors 64B (e.g., copper) intermingles, so that metal-to-metal bonds are also formed. Hence, the resulting bonds between the second integrated circuit dies 50B, the bonding layer 122, and the bond pads 124 include both dielectric-to-dielectric bonds and metal-to-metal bonds.

As illustrated, the second integrated circuit dies 50B include conductive vias 56B. Although, in some embodiments (not specifically illustrated), the second integrated circuit dies 50B may not include conductive vias 56, and external connection to the die structure 100 may be formed through the integrated circuit die 70. The illustrated die structure 100 includes three layers of integrated circuit dies (e.g., the integrated circuit die 70, one or more first integrated circuit dies 50A, and one or more second integrated circuit dies 50B). In the embodiments in which the conductive vias 56 are excluded from the second integrated circuit dies 50B, the second integrated circuit dies 50B are the upper layer in the die structure 100, and external electrical connection is subsequently formed along the integrated circuit die 70. In other embodiments (not specifically illustrated), the die structure 100 may include more than three layers of integrated circuit dies, such as more than two layers of the integrated circuit dies 50 attached to the integrated circuit die 70. Conversely, the die structure 100 may include two layers of integrated circuit dies, such as one layer of the integrated circuit dies 50 attached to the integrated circuit die 70.

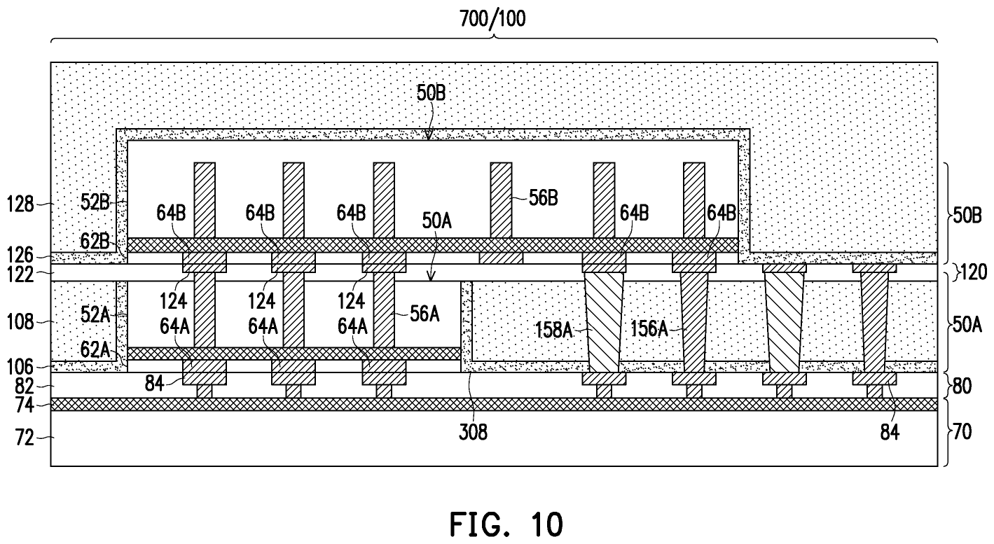

In FIG. 10, a buffer layer 126 is deposited over the first integrated circuit dies 50A and the through vias 156A/158A and around the second integrated circuit dies 50B. The buffer layer 126 is a liner layer that an overlying gap-fill dielectric will be formed on. The buffer layer 126 may protect the second integrated circuit dies 50B and underlying conductive features from damage when subsequently forming the gap-fill dielectric. The buffer layer 126 may be formed from one of the candidate materials and by one of the candidate methods described above in connection with the buffer layer 106. The buffer layer 126 may be formed of the same material as the buffer layer 106, or may include a different material than the buffer layer 106.

A gap-fill dielectric 128 is then form on the buffer layer 126. The gap-fill dielectric 128 and the buffer layer 126 are around and between the second integrated circuit dies 50B in the device region 70D. Initially, the gap-fill dielectric 128 and the buffer layer 126 may bury or cover the second integrated circuit dies 50B, such that the top surfaces of the gap-fill dielectric 128 and the buffer layer 126 are above the top surfaces of the second integrated circuit dies 50B.

The gap-fill dielectric 128 may be formed from one of the candidate materials and by one of the candidate methods as described above in connection with the gap-fill dielectric 108. The gap-fill dielectric 128 may be formed of the same material as the gap-fill dielectric 108, or may include a different material than the gap-fill dielectric 108.

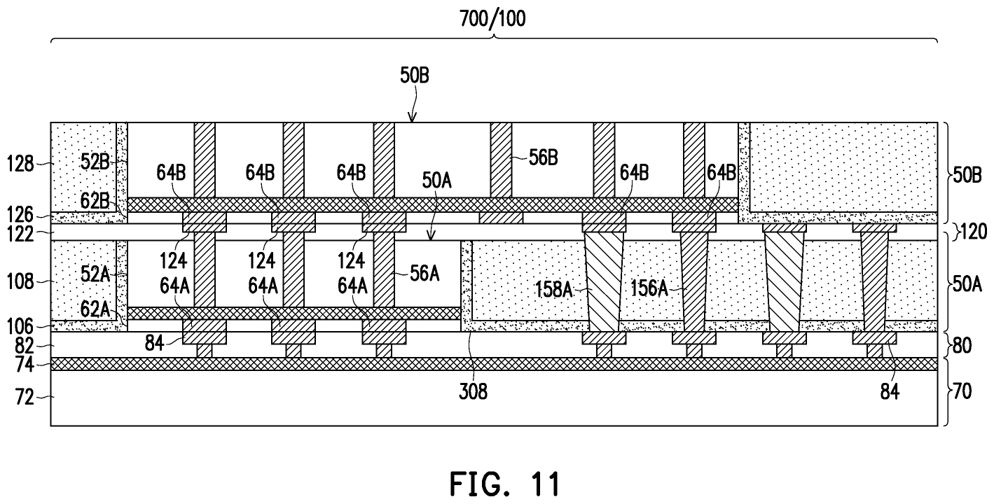

In FIG. 11, a removal process is performed to level the top surfaces of the gap-fill dielectric 128 and the buffer layer 126 with the inactive surfaces of the second integrated circuit dies 50B. In some embodiments, a planarization process such as a CMP, an etch-back process, combinations thereof, or the like is utilized. After the planarization process, surfaces of the gap-fill dielectric 128, the buffer layer 126, and the second integrated circuit dies 50B (including the semiconductor substrates 52B) are substantially coplanar (within process variations). The conductive vias 56B of the second integrated circuit dies 50B may remain buried by the semiconductor substrates 52B after this removal process.

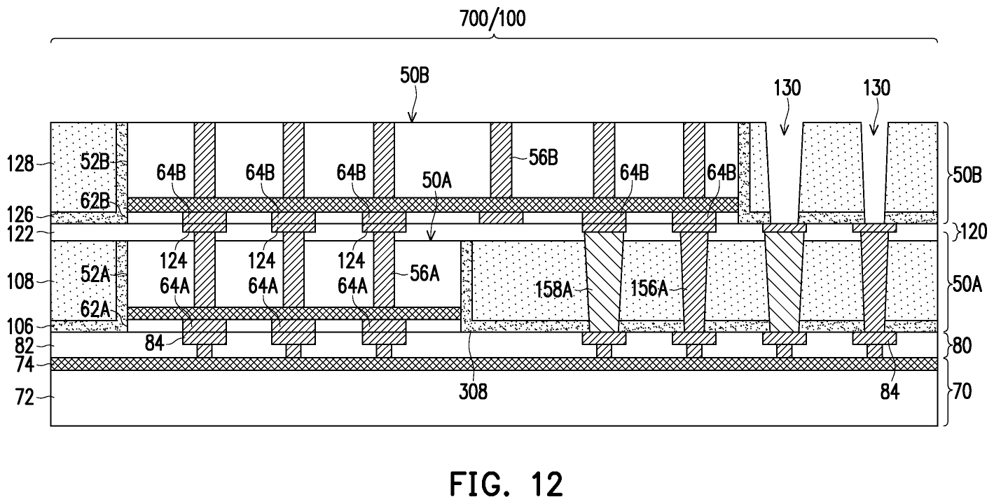

In FIG. 12, an etching process is performed to form openings 130 that expose some of the bond pads 124, such as bond pads 124 which do not have the second integrated circuit dies 50B directly attached. The openings 130 may be formed using any suitable process such as photolithography and etching. For example, the openings 110 can be formed by etching, milling, laser techniques, a combination thereof, or the like. The etching process may include one or more isotropic etching and/or anisotropic etching processes. For example, a first etching process may be used to form the openings 130 to expose the buffer layer 126, and a second etching process may be used to extend the openings 130 to expose the underlying bond pads 124.

As discussed in greater detail below, the openings 130 may have a variety of shapes and dimensions. For example, some of the openings 130A will be used for active through vias while others of the openings 130D will be used for dummy through vias. As such, the openings 130A and the openings 130B may have same, similar, or different shapes as well as same, similar, or different dimensions.

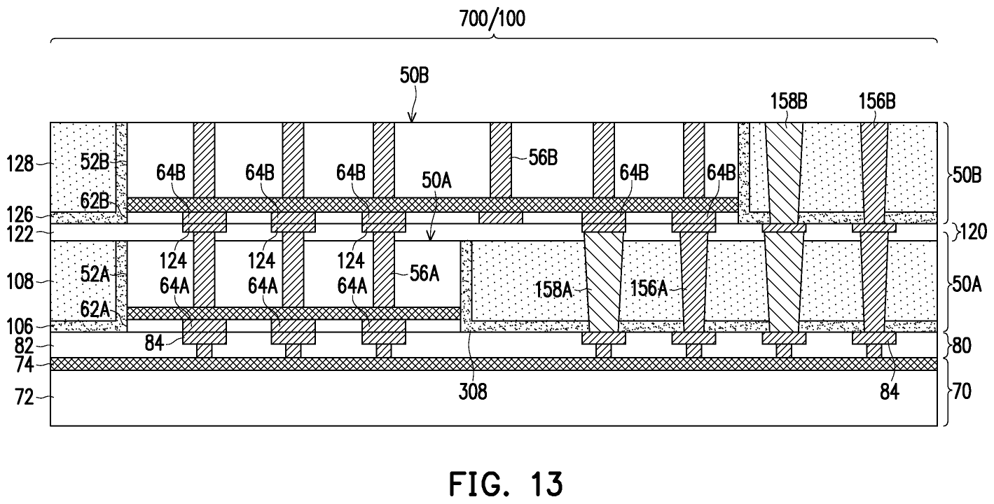

In FIG. 13, the openings 130 are filled with conductive material to form through vias 156B/158B. The through vias 156B/158B include active through vias 156B and dummy through vias 158B. The active through vias 156B will be electrically connected to other integrated circuits of the die structure (e.g., the integrated circuit dies 50/70 and the active through vias 156A). The dummy through vias 158B will be electrically isolated from the integrated circuits of the die structure (e.g., the integrated circuit dies 50/70 as well as the active through vias 156). In some embodiments, the dummy through vias 158B may be connected to conductive elements on or connected to some of the integrated circuit dies 50/70, however, such that the dummy through vias 158B remain electrically isolated from the integrated circuits within those integrated circuit dies 50/70. The active through vias 156B and the dummy through vias 158B may be formed in a variety of layouts that differ from the cross-section as illustrated in FIG. 13 for simplicity. For example, FIGS. 16A through 16K are provided to illustrate and describe various other arrangement styles that may be utilized for either or both of the through vias 156A/158A and the through vias 156B/158B. Note that by forming the openings 130 and the through vias 156B/158B at this part of the process ensures that the buffer layer 126 and the gap-fill dielectric 128 may be formed crack-free, seam-free, and at a higher deposition rate and yield.

In accordance with some embodiments, a thin barrier layer may be conformally deposited in the openings 130, such as by CVD, ALD, PVD, thermal oxidation, a combination thereof, or the like. The barrier layer may be formed of an oxide, a nitride, combinations thereof, or the like. A conductive material may be formed over the barrier layer and in the openings 130. The conductive material may be formed by an electro-chemical plating process, CVD, ALD, PVD, a combination thereof, or the like. Examples of conductive materials include copper, tungsten, aluminum, silver, gold, the like, or alloys or combinations thereof. Excess conductive material and barrier layer is removed from a surface of the gap-fill dielectric 128 and the buffer layer 126 by, for example, a CMP. The remaining portions of the barrier layer and conductive material in the openings 130 form the through vias 156B/158B.

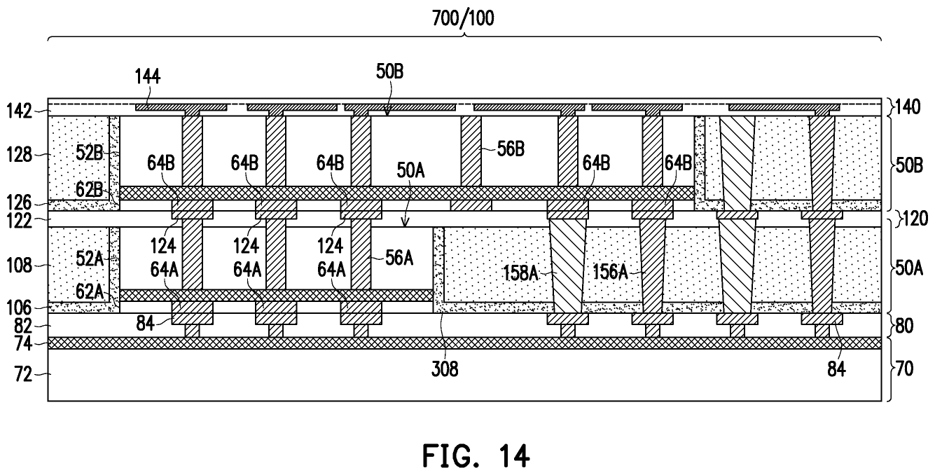

In FIG. 14, a redistribution structure 140 is formed over the back side surfaces of the second integrated circuit dies 50B as well as over the buffer layer 126, the gap-fill dielectric 128, and the through vias 156B/158B. The redistribution structure 140 includes dielectric layers 142 and metallization layers 144 (sometimes referred to as redistribution layers or redistribution lines) embedded in the dielectric layers 142. For example, the redistribution structure 140 may include a plurality of metallization layers 144 separated from each other by respective dielectric layers 142. The metallization layers 144 of the redistribution structure 140 may be electrically coupled to the conductive vias 56B of the second integrated circuit dies 50B and to the through vias 156B/158B (e.g., the active through vias 156B). Although illustrated as not being connected to the dummy through vias 158B, in some embodiments the metallization layers 144 may be connected to the dummy through vias 156B to enhance thermal dissipation benefits.

In some embodiments, the dielectric layers 142 are formed of a polymer, which may be a photo-sensitive material such as PBO, polyimide, a BCB-based polymer, or the like. In other embodiments, the dielectric layers 142 are formed of a nitride such as silicon nitride; an oxide such as silicon oxide, PSG, BSG, BPSG; or the like. The dielectric layers 142 may be formed by spin coating, lamination, CVD, the like, or a combination thereof. After each dielectric layer 142 is formed, it is then patterned to form openings exposing underlying conductive features, such as portions of the underlying conductive vias 56B, through vias 156B/158B, and/or underlying metallization layers 144. The patterning may be by an acceptable process, such as by exposing the dielectrics layers to light when the dielectric layers 142 are a photo-sensitive material, or by etching using, for example, an anisotropic etch. If the dielectric layers 142 are photo-sensitive materials, the dielectric layers 142 can be developed after the exposure.

The metallization layers 144 include conductive vias and conductive lines. The conductive vias extend through respective dielectric layers 142, and the conductive lines extend along respective dielectric layers 142. As an example to form a metallization layer 144, a seed layer (not separately illustrated) is formed over the respective underlying conductive features. For example, the seed layer can be formed on a respective dielectric layer 142 and in the openings through the respective dielectric layer 142. In some embodiments, the seed layer is a metal layer, which may be a single layer or a composite layer comprising a plurality of sub-layers formed of different materials. In some embodiments, the seed layer comprises a titanium layer and a copper layer over the titanium layer. The seed layer may be formed using a deposition process, such as PVD or the like.

A photoresist is then formed and patterned on the seed layer. The photoresist may be formed by spin coating or the like and may be exposed to light for patterning. The pattern of the photoresist corresponds to the metallization layer. The patterning forms openings through the photoresist to expose the seed layer. A conductive material is formed in the openings of the photoresist and on the exposed portions of the seed layer. The conductive material may be formed by plating, such as electroless plating or electroplating from the seed layer, or the like. The conductive material may comprise a metal or a metal alloy, such as copper, titanium, tungsten, aluminum, the like, or combinations thereof. Then, the photoresist and portions of the seed layer on which the conductive material is not formed are removed. The photoresist may be removed by an acceptable ashing or stripping process, such as using an oxygen plasma or the like. Once the photoresist is removed, exposed portions of the seed layer are removed, such as by using an acceptable etching process, such as by wet or dry etching. The remaining portions of the seed layer and conductive material form a metallization layer 144 for the redistribution structure 140.

The illustrated redistribution structure 140 represents a simplified example. More or fewer dielectric layers 142 and metallization layers 144 than illustrated may be formed in the redistribution structure 140 by performing the previously described steps a desired quantity of times. In addition, routing of the metallization layers 144 may electrically connect the conductive vias 56B of the second integrated circuit dies 50B to the through vias 156B/158B (e.g., the active through vias 156B).

In FIG. 15, optionally, additional features may be formed for attaching the die structures 100 to package components. In some embodiments, under bump metallurgies (UBMs) 146 are formed for external connection to the redistribution structure 140. Further, conductive connectors 148 may be formed on the UBMs 146. The conductive connectors 148 may be used to connect the UBMs 146 to a package component such as an interposer, a package substrate, or the like.

The UBMs 146 may be formed through an upper dielectric layer 142 of the redistribution structure 140. The UBMs 146 have bump portions on and extending along the major surface of the upper dielectric layer 142, and have via portions extending through the upper dielectric layer 142 to physically and electrically couple an upper metallization layer 144 of the redistribution structure 140. As a result, the UBMs 146 are electrically coupled to the conductive vias 56B of the second integrated circuit dies 50B and to the through vias 156B/158B. The UBMs 146 may be formed of the same material(s) as the metallization layer(s) 144. In some embodiments, the UBMs 146 have a different size than the metallization layer(s) 144.

The conductive connectors 148 may be formed on the UBMs 146. The conductive connectors 148 may be ball grid array (BGA) connectors, solder balls, metal pillars, controlled collapse chip connection (C4) bumps, micro bumps, electroless nickel-electroless palladium-immersion gold technique (ENEPIG) formed bumps, or the like. The conductive connectors 148 may include a conductive material such as solder, copper, aluminum, gold, nickel, silver, palladium, tin, the like, or a combination thereof. In some embodiments, the conductive connectors 148 are formed by initially forming a layer of a reflowable material (e.g., solder) through evaporation, electroplating, printing, solder transfer, ball placement, or the like. Once a layer of solder has been formed on the structure, a reflow may be performed in order to shape the material into the desired bump shapes. In another embodiment, the conductive connectors 148 include metal pillars (such as copper pillars) formed by a sputtering, printing, electro plating, electroless plating, CVD, or the like. The metal pillars may be solder-free and have substantially vertical sidewalls. In some embodiments, a metal cap layer is formed on the top of the metal pillars. The metal cap layer may include nickel, tin, tin-lead, gold, silver, palladium, indium, nickel-palladium-gold, nickel-gold, the like, or a combination thereof, which may be formed by a plating process.

In FIG. 16, a singulation process may be performed along scribe line regions, e.g., between adjacent device regions 70D (not separately illustrated) for incorporation of the die structure 100 into an integrated circuit package. The singulation process may include a sawing process, a laser cutting process, or the like. The singulation process singulates the device region 70D from the adjacent device regions. The resulting singulated die structure 100 is from the device region 70D. The die structure 100 includes multiple tiers of integrated circuit dies (e.g., the integrated circuit die 70 and the integrated circuit dies 50). In the previously illustrated embodiments, the die structure 100 includes a first tier of the first integrated circuit dies 50A and a second tier of the second integrated circuit dies 50B, although any quantity of tiers of integrated circuit dies 50 may be included in the die structure 100.

Note that the previously described embodiment die structures 100 are components that may be subsequently implemented in an integrated circuit package. The integrated circuit dies 50 of a die structure 100 may be heterogeneous dies. Packaging the die structure 100 in lieu of or in addition to packaging integrated circuit dies individually may allow heterogeneous dies to be integrated with a small footprint. In some embodiments, the integrated circuit package is formed by attaching one or more die structures 100 to an additional component, such as an interposer, a package substrate, or the like. In some embodiments (not specifically illustrated), an integrated circuit package is formed by encapsulating the die structure 100 and forming redistribution lines on the encapsulant to fan-out connections from the die structure 100.

Referring to FIG. 16, the integrated circuit package 200 includes die structures 100 (e.g., a first die structure 100A and a second die structure 100B) attached to a routing structure 202. In this integrated circuit package 200, the die structures 100 include the conductive connectors 148. The first die structure 100A may be different than the second die structure 100B. For example, the first die structure 100A may be a memory device while the second die structure 100B may be a logic device. The routing structure 202 may be an interposer, a redistribution structure, or the like. In the illustrated embodiment, the die structures 100 are attached to the routing structure 202 with the conductive connectors 148. The conductive connectors 148 may be reflowed to attach UBMs of the die structures 100 to die connectors of the routing structure 202. An underfill (not separately illustrated) may be formed around the conductive connectors 148, and between the routing structure 202 and the die structures 100. After the die structures 100 are attached to the routing structure 202, an encapsulant 204 is formed on and around the various components. The encapsulant 204 encapsulates the die structures 100. Subsequently, the routing structure 202 may be singulated (if necessary) and attached to a package substrate 206.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures (e.g., the individual integrated circuit dies 50/70 and/or the die structure 100) as well as the final structure (e.g., the integrated circuit package and/or a subsequent package structure). Additionally, the structures and methods disclosed herein may be used in conjunction with testing methodologies that incorporate intermediate verification of known good dies to increase the yield and decrease costs.

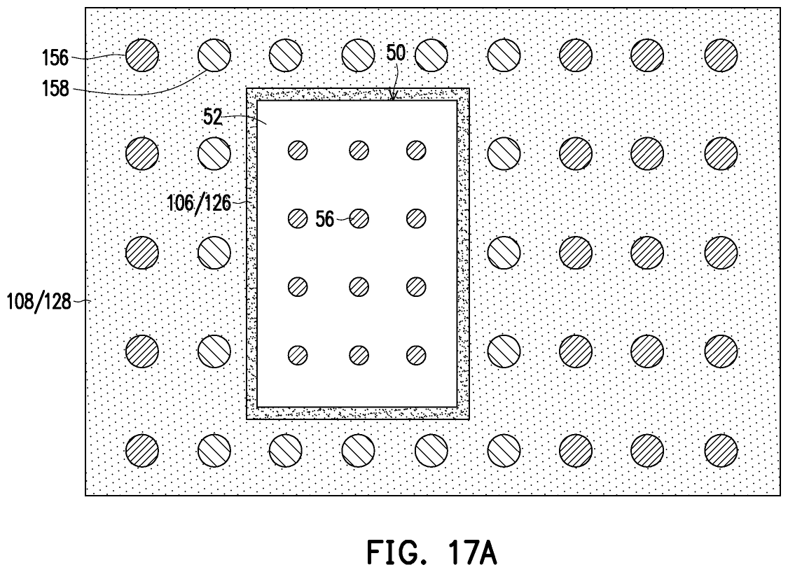

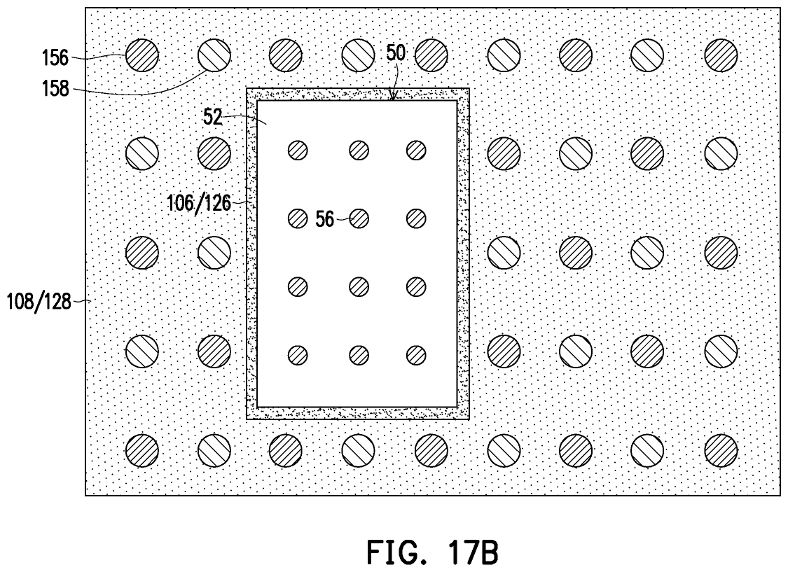

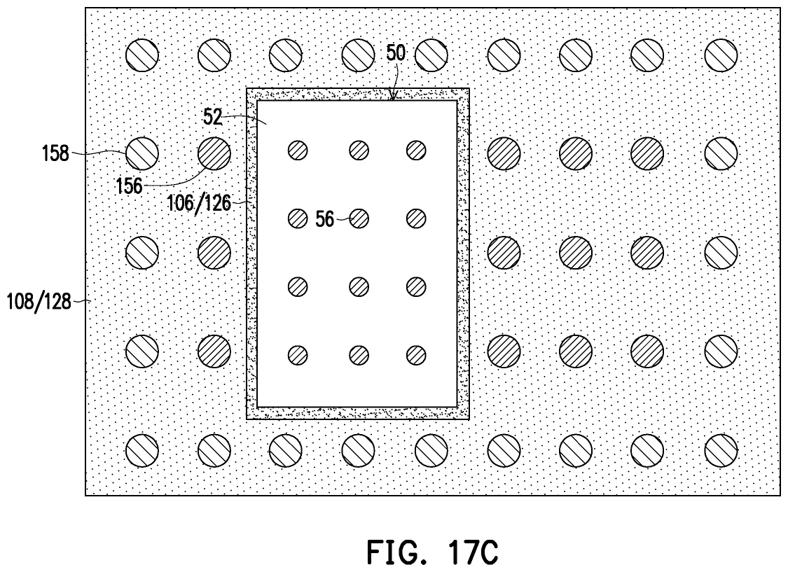

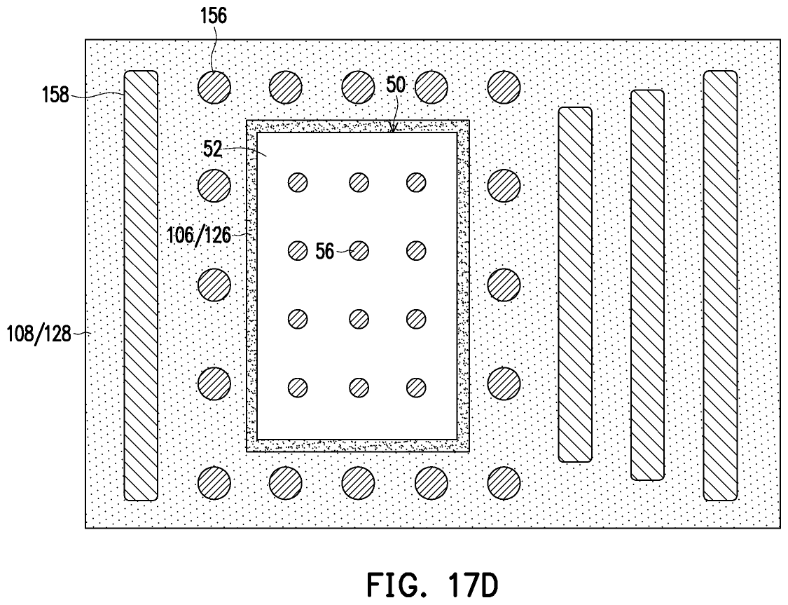

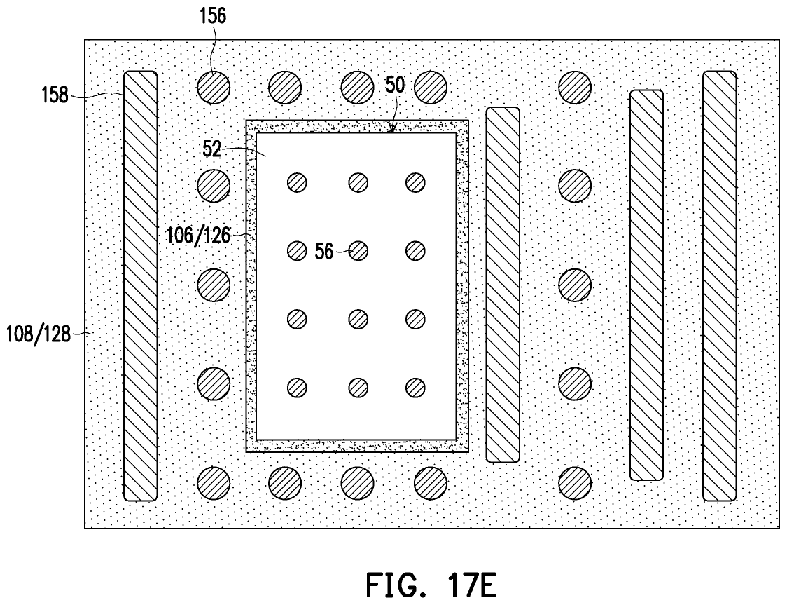

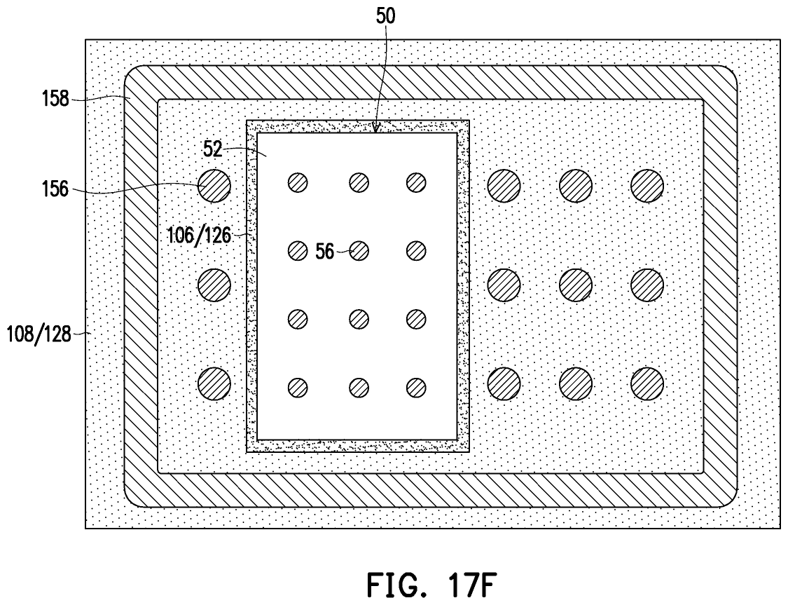

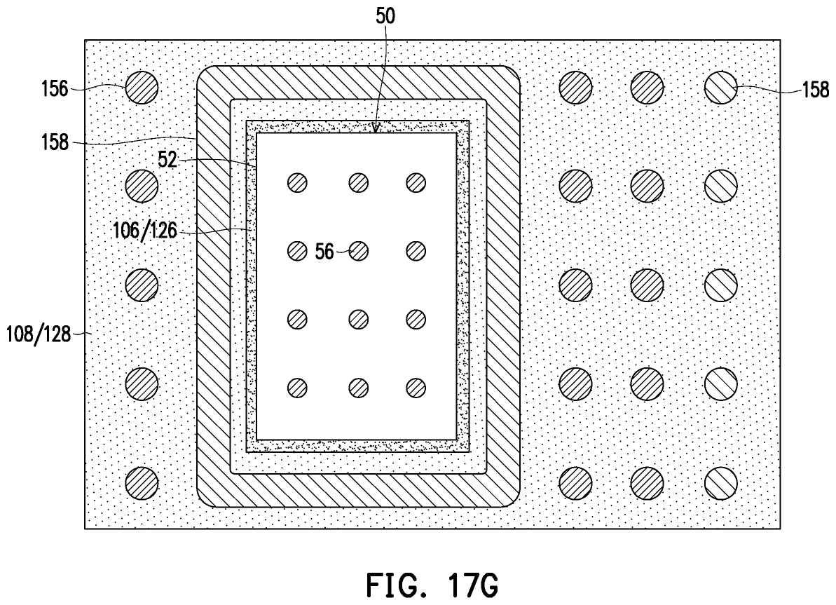

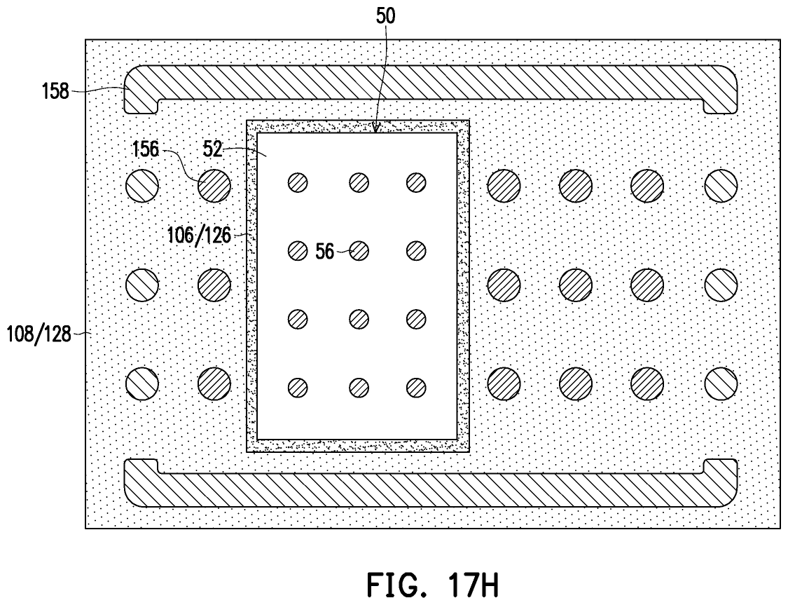

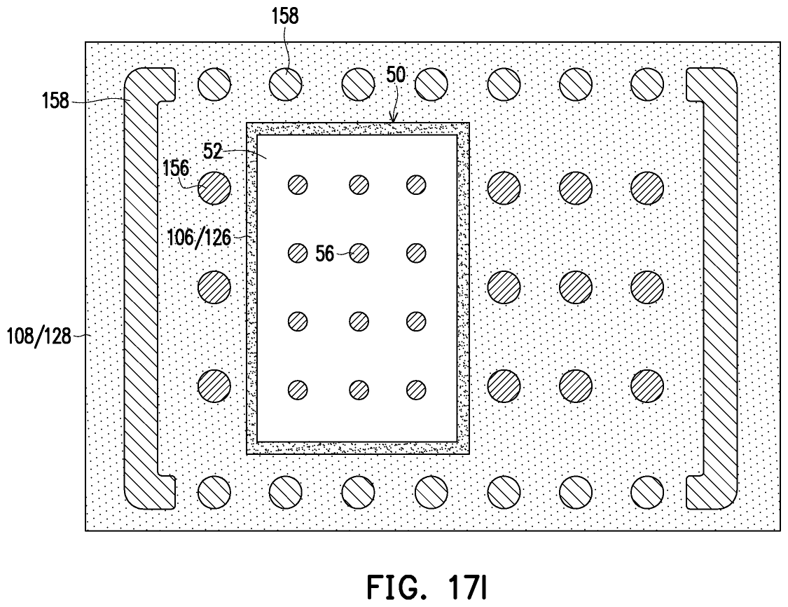

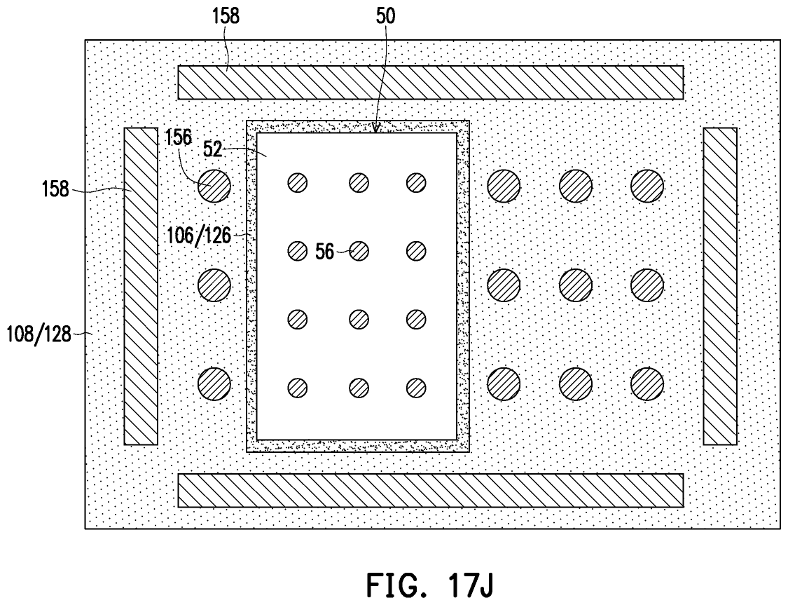

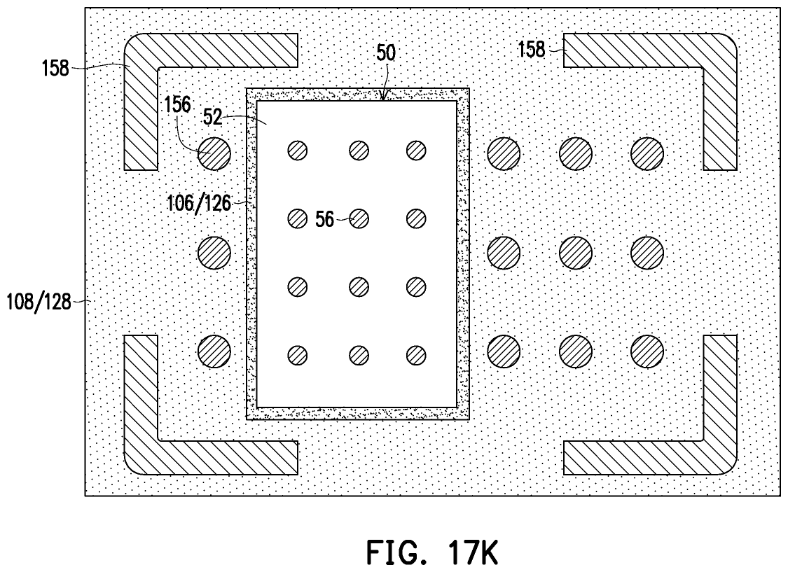

FIGS. 17A through 17I illustrate plan views (e.g., top-down views) of intermediate stages of the die structure 100, in accordance with various embodiments. In particular, various layout styles or schemes are provided for the dummy through vias 158A in relation to the first integrated circuit dies 50A and the active through vias 156A and for the dummy through vias 158B in relation to the second integrated circuit dies 50B and the active through vias 156B. The illustrated embodiments may represent some or all of the layers of integrated circuit dies 50. For example, the first tier (e.g., comprising the first integrated circuit dies 50A) and the second tier (e.g., comprising the second integrated circuit dies 50B) may include same, similar, or differing layout styles.

FIGS. 17A through 17C represent embodiments wherein the dummy through vias 158 of a particular tier are arranged in a dotted pattern or grid layout. For example, in the plan view the dummy through vias 158 may have a shape and size similar to that of the active through vias 156. In the illustrated embodiments, these shapes may be oval or elliptical (e.g., circular). In other embodiments (not specifically illustrated), either or both of the types of through vias 156/158 may have other shapes such as being rectangular (e.g., square) cross-shaped, strip-shaped, annular or any suitable shape, including rounded versions thereof. In addition, a diameter of the dummy through vias 158 may be less than, greater than, or substantially the same as a diameter of the active through vias 156. The dummy through vias 158 having a greater diameter will provide increased thermal dissipation benefits, wherein the dummy through vias 158 having a lesser diameter will allow for greater density of the active components such as the active through vias 156 and the integrated circuit dies 50.

Referring to FIG. 17A, the active through vias 156 may be proximal to the integrated circuit die 50 to benefit connectivity there-between and with overlying or underlying components (e.g., other integrated circuit dies 50/70). This layout is advantageous when components carrying or generating higher amounts of heat are located along edges of the groups of electrically connected components (e.g., integrated circuit dies 50 and active through vias 156). As a result, those components are proximal to the dummy through vias 158, which can provide sufficient thermal dissipation.

Referring to FIG. 17B, the active through vias 156 and the dummy through vias 158 may be interspersed with one another (e.g., an alternating grid layout). This layout is advantageous to ensure that each electrically connected component is proximal to some of the dummy through vias 158. As a result, the dummy through vias 158 are able to dissipate heat from all such components which may be located in interior regions of the particular tier. In addition, these benefits are achieved without designing the layout such that the components carrying or generating higher amounts of heat are located along edges of the groups of electrically connected components (e.g., integrated circuit dies 50 and active through vias 156). Although the dummy through vias 158 and the active through vias 156 are illustrated in an alternating scheme, it should be appreciated that they may be arranged in alternating clusters or in an irregular pattern.

Referring to FIG. 17C, the dummy through vias 158 may be formed in a frame or perimeter (e.g., a discontinuous frame or ring) around the electrically connected elements (e.g., integrated circuit die 50 and active through vias 156). This layout achieves similar benefits of the embodiments described in connection with FIG. 17A. Additionally, the frame layout ensures that heat from the electrically connected elements has less influence on or dissipation into any adjacent package components, and vice versa.

FIGS. 17D through 17I represent embodiments wherein some or all of the dummy through vias 158 of a particular tier have bar shapes or strip shapes (see FIGS. 17D and 17E), continuous frame shapes (see FIGS. 17F and 17G), and/or bracket shapes (see FIGS. 17H and 17I). For example, in the plan view each of these dummy through vias 158 may have a larger footprint than each of the active through vias 156. Note that the dummy through vias 158 may include any combinations of such designs while also including some of the dummy through vias 158 in the dotted layouts described above.

Referring to FIG. 17D, some of the dummy through vias 158 may have bar shapes and be located on outer regions of the particular tier. Notes the bar shapes of the dummy through vias 158 may be formed in conjunction with any of the above or subsequently described layouts. In some embodiments, the active through vias 156 may be located in an interior region of the particular tier (e.g., proximal to the integrated circuit die 50) to benefit connectivity there-between and with overlying or underlying components (e.g., other integrated circuit dies 50/70). This layout achieves similar benefits as described above (e.g., FIGS. 17A and 17C), while also improving thermal dissipation and taking up less space, thereby allowing more available space for the electrically connected components (e.g., integrated circuit die 50 and active through vias 156).

Referring to FIG. 17E, some of the dummy through vias 158 may have bar shapes and may be interspersed (e.g., alternating) or scattered with respect to the active through vias 156. This layout achieves similar benefits as described above (e.g., FIGS. 17B and 17D), such as providing thorough thermal dissipation from the electrically connected elements (e.g., integrated circuit die 50 and active through vias 156) in a wider variety of designs and layouts thereof.

Referring to FIG. 17F, the dummy through vias 158 may be or include a continuous frame or perimeter (e.g., a continuous ring) around the electrically connected elements (e.g., integrated circuit die 50 and active through vias 156). This layout achieves similar benefits as described above (e.g., FIGS. 17A, 17C, and 17D).

In FIG. 17G, the dummy through vias 158 may be or include a continuous frame or perimeter (e.g., a continuous ring) around the integrated circuit die 50. For example, the continuous frame of the dummy through vias 158 may be proximal to the integrated circuit die 50 and within the active through vias 156. This layout achieves similar benefits as described above (e.g., FIGS. 17B and 17E), such as providing thermal dissipation for components carrying or generating some of the greatest amounts of heat (e.g., the integrated circuit dies 50).

As discussed above, combinations of the above described layouts may be utilized. For example, in FIGS. 17H and 17I, the dummy through vias 158 may include brackets around the integrated circuit die 50, the active through vias 156, and others of the dummy through vias 158. FIG. 17H illustrates a long bracket layout, and FIG. 17I illustrates a short bracket layout. The brackets of FIGS. 17H and 17I may also be referred to as an open frame layout. In addition, FIGS. 17J and 17K illustrate examples of combining, e.g., aspects of the embodiments of FIGS. 17C and 17F by forming segments around the perimeter of the particular tier. For example, FIG. 17J illustrates bar shapes arranged in a frame, and FIG. 17K illustrates corner segments arranged in a frame. As a result, the components of the frame are discontinuous with one another. These layouts achieve the various benefits describe above and particularly wherein the discontinuity provides greater flexibility and robustness during high physical and/or thermal stress processes.

Various advantages are achieved. In particular, the disclosed embodiments provide layouts of dummy through vias 158 in relation to integrated circuit dies 50 and active through vias 156 to improve thermal dissipation in an assortment of ways. The dummy through vias 158 may be formed simultaneously with the active through vias 156, which ensures that no additional processing steps (or few additional process steps) are included to form the dummy through vias 158. The dummy through vias 158 may have similar shapes as the active through vias. In addition, the dummy through vias 158 may include bar shapes for improved thermal dissipation in proportion to the amount of space used by the dummy through vias 158. Further, the dummy through vias 158 may include frame shapes (e.g., continuous ring shapes) for additional thermal dissipation benefits. Combinations of these may be utilized within a single tier or between different tiers of a die structure 100. Moreover, the dummy through vias 158 may be formed for a consistent density of conductive elements, which reduces effects of thermal expansion such as wafer warpage.

In an embodiment, a method includes: forming first bond pads along a wafer; bonding a first die to a first set of the first bond pads, the first die being electrically connected to the wafer; depositing a gap-fill dielectric over the wafer and around the first die; forming openings in the gap-fill dielectric to expose a second set and a third set of the first bond pads; forming first active through vias in physical contact with the second set of the first bond pads and first dummy through vias in physical contact with the third set of the first bond pads, the first active through vias being electrically connected to the wafer, the first dummy through vias being electrically isolated from the wafer; forming second bond pads along a back side of the first die, an upper surface of the first active through vias, and an upper surface of the first dummy through vias; and bonding a second die to the first die and to a first active via of the first active through vias. In another embodiment, the second die is bonded to a first dummy via of the first dummy through vias. In another embodiment, an integrated circuit of the second die is electrically isolated from the first dummy via of the first dummy through vias. In another embodiment, in a plan view the first active through vias and the first dummy through vias have an alternating grid layout. In another embodiment, in a plan view the first dummy through vias are arranged in a frame around the first die and the first active through vias. In another embodiment, the first dummy through vias comprise a continuous ring around the first die and the first active through vias. In another embodiment, the method further includes: depositing an additional gap-fill dielectric over the gap-fill dielectric and around the second die; forming additional openings in the additional gap-fill dielectric to expose some of the second bond pads; and forming additional through vias in the additional openings. In another embodiment, the additional through vias comprise a second active through via being electrically connected to a second active via of the first active through vias, and wherein the additional through vias comprise a second dummy through via being electrically connected to a second dummy via of the first dummy through vias.

In an embodiment, a semiconductor device includes: a first top die bonded to a bottom die, a first bond pad electrically connecting the first top die to the bottom die; a first active through via over the bottom die, a second bond pad electrically connecting the first active through via to the bottom die; a first dummy through via over the bottom die, the first dummy through via being in physical contact with a third bond pad; and a dielectric layer encapsulating the first top die, the first active through via, and the first dummy through via. In another embodiment, the semiconductor device further includes: a second top die bonded to the first top die, a fourth bond pad electrically connecting the second top die to the first top die, a fifth bond pad electrically connecting the second top die to the first active through via; a redistribution structure over the second top die; a second active through via and a second dummy through via encapsulated in the dielectric layer; a third active through via over and electrically connected to the second active through via; and a third dummy through via over and electrically connected to the second dummy through via. In another embodiment, in a plan view the first dummy through via is circular and the second dummy through via is bar-shaped. In another embodiment, in the plan view the third dummy through via is bar-shaped. In another embodiment, in the plan view the third dummy through via is circular. In another embodiment, a sixth bond pad electrically connects the second top die to the first dummy through via, and wherein the first dummy through via is electrically isolated from an integrated circuit of the second top die.

In an embodiment, a semiconductor device includes: a first die level, the first die level comprising a first die; a second die level, the second die level comprising: a second die; first active through vias; and first dummy through vias, in a first plan view the first dummy through vias comprising a discontinuous frame around the second die; and a first bonding structure interposed between the first die level and the second die level, the first bonding structure electrically connecting the first die to the second die, the first bonding structure electrically connecting the first die to the first active through vias. In another embodiment, the semiconductor device further includes: a third die level, the third die level comprising: a third die; a second active through via; and a second dummy through via, in a second plan view the second dummy through via comprising a continuous frame around the third die; and a second bonding layer interposed between the second die level and the third die level, the second bonding layer electrically connecting the second die to the first die. In another embodiment, the second bonding layer electrically connects the third die to a first active via of the first active through vias, and wherein the second bonding layer electrically connects the third die to a first dummy via of the first dummy through vias. In another embodiment, the second bonding layer electrically connects a second active via of the first active through vias to the second active through via. In another embodiment, the second bonding layer electrically connects a second dummy via of the first dummy through vias to the second dummy through via, and wherein the first dummy through vias and the second dummy through via are electrically isolated from integrated circuits of the first die, the second die, and the third die. In another embodiment, in the first plan view the first dummy through vias comprise circular shapes and bar shapes.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming first bond pads along a wafer;
bonding a first die to a first set of the first bond pads, the first die being electrically connected to the wafer;
depositing a gap-fill dielectric over the wafer and around the first die;
forming openings in the gap-fill dielectric to expose a second set and a third set of the first bond pads;
forming first active through vias in physical contact with the second set of the first bond pads and first dummy through vias in physical contact with the third set of the first bond pads, the first active through vias being electrically connected to the wafer, the first dummy through vias being electrically isolated from the wafer;
forming second bond pads along a back side of the first die, an upper surface of the first active through vias, and an upper surface of the first dummy through vias; and
bonding a second die to the first die and to a first active via of the first active through vias.

2. The method of claim 1, wherein the second die is bonded to a first dummy via of the first dummy through vias.

3. The method of claim 2, wherein an integrated circuit of the second die is electrically isolated from the first dummy via of the first dummy through vias.

4. The method of claim 1, wherein in a plan view the first active through vias and the first dummy through vias have an alternating grid layout.

5. The method of claim 1, wherein in a plan view the first dummy through vias are arranged in a frame around the first die and the first active through vias.

6. The method of claim 5, wherein the first dummy through vias comprise a continuous ring around the first die and the first active through vias.

7. The method of claim 1, further comprising:
depositing an additional gap-fill dielectric over the gap-fill dielectric and around the second die;
forming additional openings in the additional gap-fill dielectric to expose some of the second bond pads; and
forming additional through vias in the additional openings.

8. The method of claim 7, wherein the additional through vias comprise a second active through via being electrically connected to a second active via of the first active through vias, and wherein the additional through vias comprise a second dummy through via being electrically connected to a second dummy via of the first dummy through vias.

9. A semiconductor device comprising:
a first top die bonded to a bottom die, a first bond pad electrically connecting the first top die to the bottom die;
a first active through via over the bottom die, a second bond pad electrically connecting the first active through via to the bottom die;
a first dummy through via over the bottom die, the first dummy through via being in physical contact with a third bond pad; and
a dielectric layer encapsulating the first top die, the first active through via, and the first dummy through via.

10. The semiconductor device of claim 9, further comprising:
a second top die bonded to the first top die, a fourth bond pad electrically connecting the second top die to the first top die, a fifth bond pad electrically connecting the second top die to the first active through via;
a redistribution structure over the second top die;
a second active through via and a second dummy through via encapsulated in the dielectric layer;
a third active through via over and electrically connected to the second active through via; and
a third dummy through via over and electrically connected to the second dummy through via.

11. The semiconductor device of claim 10, wherein in a plan view the first dummy through via is circular and the second dummy through via is bar-shaped.

12. The semiconductor device of claim 11, wherein in the plan view the third dummy through via is bar-shaped.

13. The semiconductor device of claim 11, wherein in the plan view the third dummy through via is circular.

14. The semiconductor device of claim 9, wherein a sixth bond pad electrically connects the second top die to the first dummy through via, and wherein the first dummy through via is electrically isolated from an integrated circuit of the second top die.

15. A semiconductor device comprising:
a first die level, the first die level comprising a first die;
a second die level, the second die level comprising:
a second die;
first active through vias; and
first dummy through vias, in a first plan view the first dummy through vias comprising a discontinuous frame around the second die; and
a first bonding structure interposed between the first die level and the second die level, the first bonding structure electrically connecting the first die to the second die, the first bonding structure electrically connecting the first die to the first active through vias.

16. The semiconductor device of claim 15, further comprising:
a third die level, the third die level comprising:
a third die;
a second active through via; and
a second dummy through via, in a second plan view the second dummy through via comprising a continuous frame around the third die; and
a second bonding layer interposed between the second die level and the third die level, the second bonding layer electrically connecting the second die to the first die.

17. The semiconductor device of claim 16, wherein the second bonding layer electrically connects the third die to a first active via of the first active through vias, and wherein the second bonding layer electrically connects the third die to a first dummy via of the first dummy through vias.

18. The semiconductor device of claim 17, wherein the second bonding layer electrically connects a second active via of the first active through vias to the second active through via.

19. The semiconductor device of claim 17, wherein the second bonding layer electrically connects a second dummy via of the first dummy through vias to the second dummy through via, and wherein the first dummy through vias and the second dummy through via are electrically isolated from integrated circuits of the first die, the second die, and the third die.

20. The semiconductor device of claim 15, wherein in the first plan view the first dummy through vias comprise circular shapes and bar shapes.
